(19) United States
(12) Patent Application Publication
(10) Pub. No.: US 2022/0344328 A1
(43) Pub. Date: Oct. 27, 2022

(54) SEMICONDUCTOR DEVICE

(71) Applicant: ROHM CO., LTD., Kyoto-shi, Kyoto (JP)

(72) Inventor: Shinya UMEKI, Kyoto-shi, Kyoto (JP)

(21) Appl. No.: 17/762,642

(22) PCT Filed: Sep. 15, 2020
(86) PCT No.: PCT/JP2020/034972

§ 371 Date: Mar. 22, 2022

(30) Foreign Application Priority Data
Sep. 27, 2019 (JP) 2019-177614

(51) Int. Cl. H01L 27/07; H01L 27/02

(52) U.S. Cl. CPC H01L 27/0727; H01L 27/0207

(57) ABSTRACT

A semiconductor device includes a first-conductivity-type semiconductor substrate that has a first main surface on one side and a second main surface on another side, a second-conductivity-type well region that is formed in a surface layer portion of the first main surface and that demarcates an active region and an outer region in the semiconductor substrate, an IGBT including a second-conductivity-type collector region formed at the active region in a surface layer portion of the second main surface and an FET structure formed at the active region in the first main surface, and a diode that includes a first-conductivity-type cathode region formed only at the outer region in the surface layer portion of the second main surface and that has the well region serving as an anode region.

### TECHNICAL FIELD

The present invention relates to a semiconductor device that includes an IGBT (Insulated Gate Bipolar Transistor) and a diode.

### BACKGROUND ART

Patent Literature 1 discloses an RC-IGBT (Reverse Conducting—IGBT). The RC-IGBT includes an IGBT and a diode that are formed integrally with a semiconductor substrate. The IGBT includes an FET structure and a collector region. The diode includes a cathode region and an anode region.

The FET structure includes a p-type base region formed in a surface layer portion on the front-surface side of the semiconductor substrate, an emitter region formed in a surface layer portion of the base region, a gate insulation layer covering both the base region and the emitter region, and a gate electrode covering the gate insulation layer. The collector region is formed in the whole area of a surface layer portion on the rear-surface side of the semiconductor substrate. The cathode region is formed in a region directly under the FET structure in the surface layer portion on the rear-surface side of the semiconductor substrate. The anode region is formed of the base region of the IGBT.

### CITATION LIST

### Patent Literature

Patent Literature 1: United States Patent Application Publication No. 2010/090248

### SUMMARY OF INVENTION

### Technical Problem

Ina structure in which the cathode region is formed directly under the FET structure, electrons injected from the emitter region flow into the cathode region when the IGBT performs a start-up operation. As a result, a snapback phenomenon occurs, and therefore switching characteristics deteriorate.

A preferred embodiment of the present invention provides a semiconductor device that is capable of restraining a deterioration in switching characteristics caused by the snapback phenomenon.

### Solution to Problem

A preferred embodiment of the present invention provides a semiconductor device including a first-conductivity-type semiconductor substrate that has a first main surface on one side and a second main surface on another side, a second-conductivity-type well region that is formed in a surface layer portion of the first main surface and that demarcates an active region and an outer region in the semiconductor substrate, an IGBT including a second-conductivity-type collector region formed at the active region in a surface layer portion of the second main surface and an FET structure formed at the active region in the first main surface, and a diode that includes a first-conductivity-type cathode region formed only at the outer region in the surface layer portion of the second main surface and that has the well region serving as an anode region.

According to this semiconductor device, it is possible to restrain a deterioration in switching characteristics that is caused by a snapback phenomenon.

The aforementioned or still other objects, features, and effects of the present invention will be clarified by the following description of preferred embodiments given below with reference to the accompanying drawings.

### BRIEF DESCRIPTION OF DRAWINGS

FIG. 1 is a plan view showing a semiconductor device according to a first preferred embodiment of the present invention.

FIG. 2 is a plan view showing a structure of a first main surface of a semiconductor substrate shown in FIG. 1.

FIG. 3 is an enlarged view of a main portion of the first main surface shown in FIG. 2.

FIG. 4 is a cross-sectional view taken along line IV-IV of FIG. 3.

FIG. 5 is a cross-sectional view taken along line V-V of FIG. 3.

FIG. 6 is a cross-sectional view taken along line VI-VI of FIG. 3.

FIG. 7 is a plan view showing a structure of a second main surface of the semiconductor substrate shown in FIG. 1.

FIG. 8 is a cross-sectional view taken along line VIII-VIII shown in FIG. 1.

FIG. 9 is a graph showing a current-voltage characteristic.

FIG. 10 corresponds to FIG. 7, and is a plan view showing a structure of a second main surface of a semiconductor device according to a second preferred embodiment of the present invention.

FIG. 11 corresponds to FIG. 7, and is a plan view showing a structure of a second main surface of a semiconductor device according to a third preferred embodiment of the present invention.

FIG. 12 is a plan view showing a semiconductor device according to a fourth preferred embodiment of the present invention.

FIG. 13 is an enlarged view of a main portion of a first main surface of the semiconductor device shown in FIG. 12.

### DESCRIPTION OF EMBODIMENTS

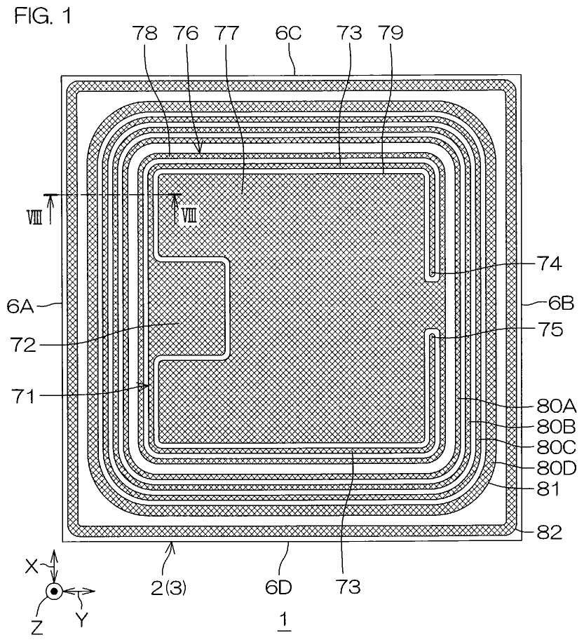

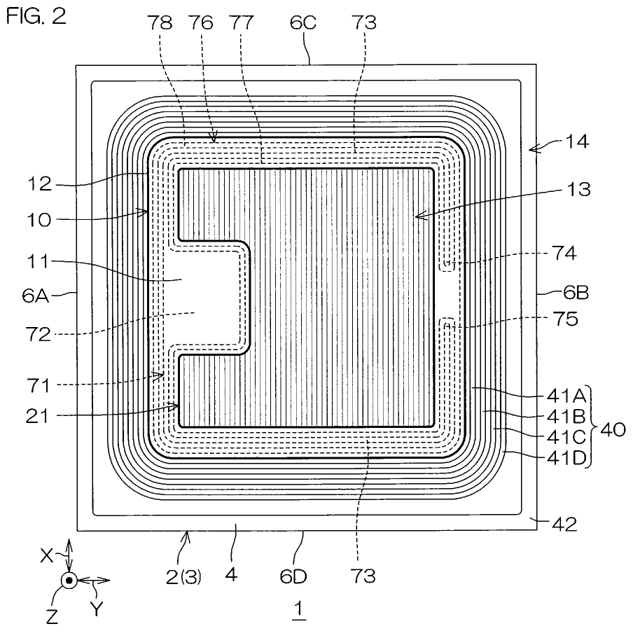

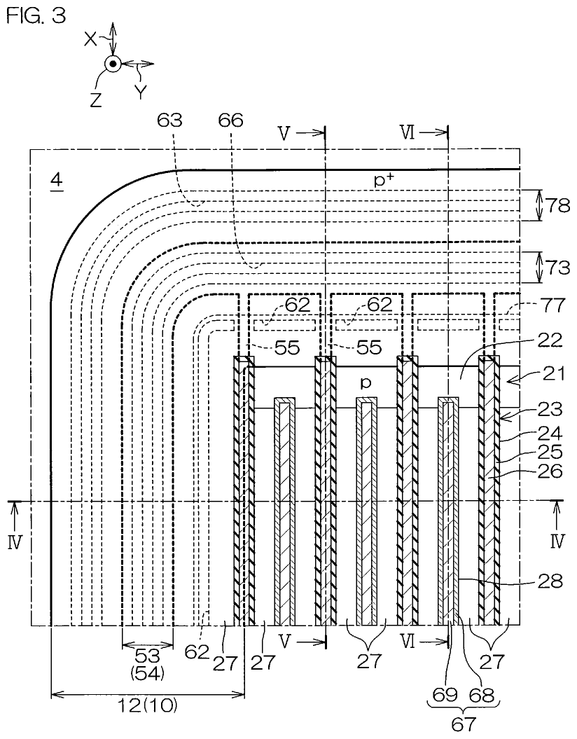

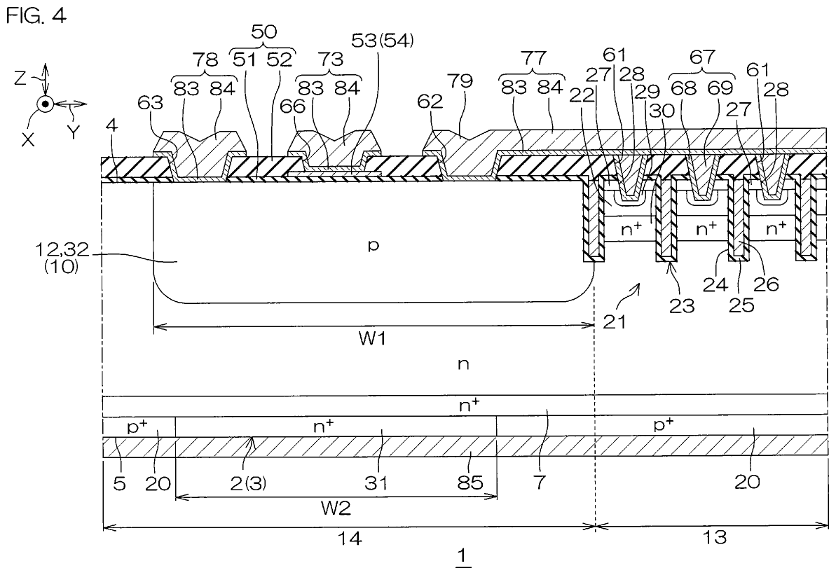

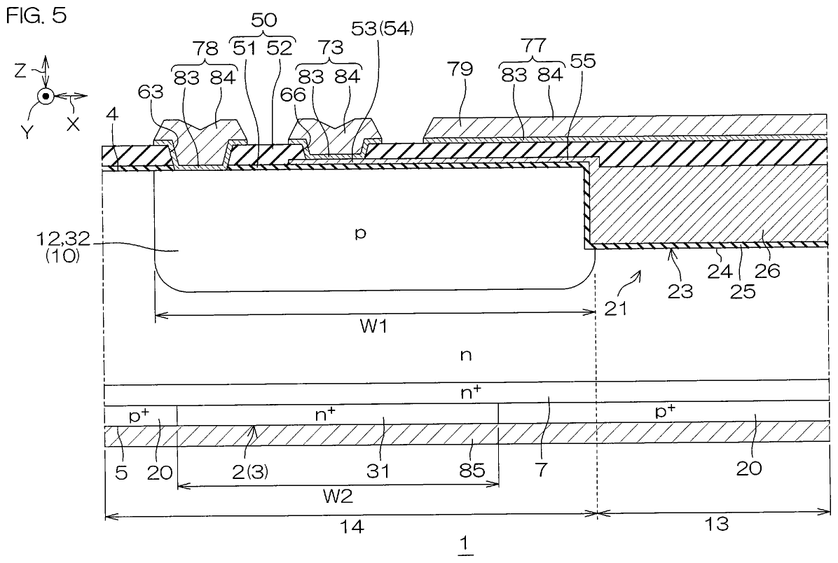

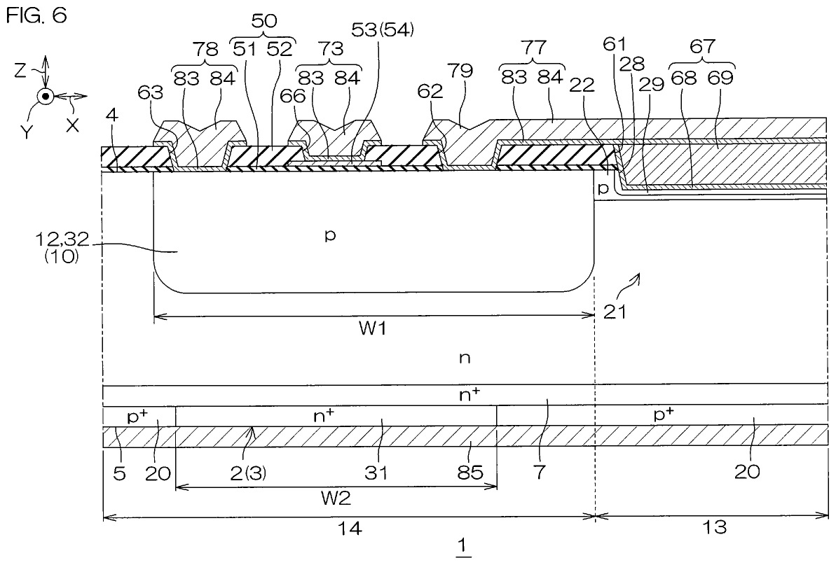

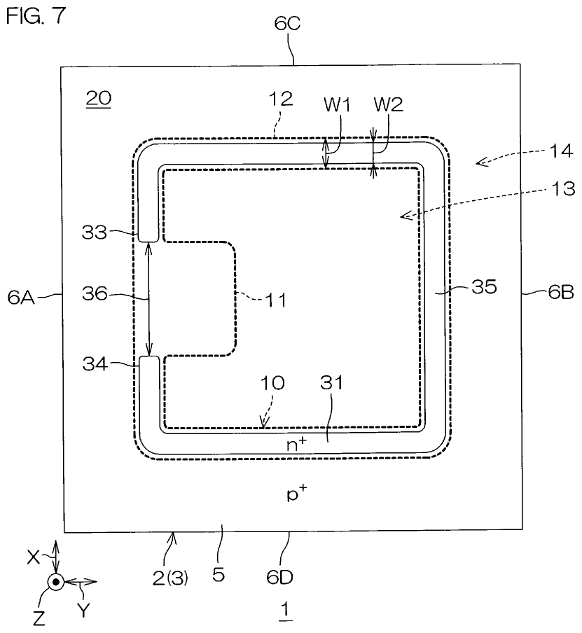

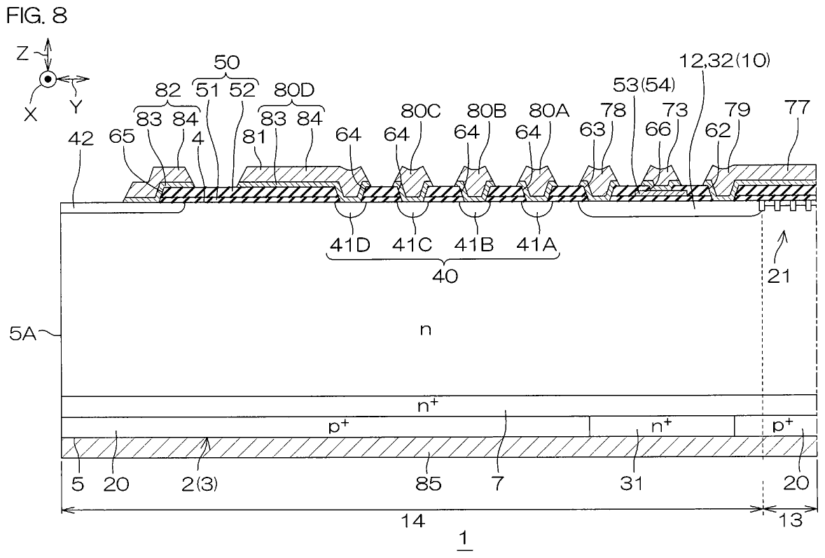

FIG. 1 is a plan view showing a semiconductor device 1 according to a first preferred embodiment of the present invention. FIG. 2 is a plan view showing a structure of a first main surface 4 of a semiconductor substrate 2 shown in FIG. 1. FIG. 3 is an enlarged view of a main portion of the first main surface 4 shown in FIG. 2. FIG. 4 is a cross-sectional view taken along line IV-IV of FIG. 3. FIG. 5 is a cross-sectional view taken along line V-V of FIG. 3. FIG. 6 is a cross-sectional view taken along line VI-VI of FIG. 3. FIG. 7 is a plan view showing a structure of a second main surface 5 of the semiconductor substrate 2 shown in FIG. 1. FIG. 8 is a cross-sectional view taken along line VIII-VIII shown in FIG. 1.

Referring to FIG. 1 to FIG. 8, the semiconductor device 1 is a semiconductor switching device that includes an RC-IGBT (Reverse Conducting-IGBT) having an IGBT (Insulated Gate Bipolar Transistor) and a diode.

The semiconductor device 1 includes an n-type silicon-made semiconductor substrate 2 formed in a rectangular parallelepiped shape. The semiconductor substrate 2 functions as a drift region 3. The semiconductor substrate 2 is formed of an FZ substrate formed through an FZ (Floating Zone) method or a CZ substrate formed through a CZ (Czochralski) method. In this embodiment, the semiconductor substrate 2 is formed of an FZ substrate. The n-type impurity concentration of the semiconductor substrate 2 may be not less than 1.0×10¹³cm⁻³ and not more than 1.0×10¹⁵ cm⁻³.

The semiconductor substrate 2 includes the first main surface 4 on one side, the second main surface 5 on the other side, and four side surfaces 6A, 6B, 6C, and 6D that connect the first main surface 4 and the second main surface 5 together. The side surfaces 6A to 6D include a first side surface 6A, a second side surface 6B, a third side surface 6C, and a fourth side surface 6D.

The first and second main surfaces 4 and 5 are each formed in a quadrangular shape in a plan view seen from their normal directions Z (which is hereinafter simply referred to as a “plan view”). The first and second side surfaces 6A and 6B extend along a first direction X, and face a second direction Y intersecting the first direction X. The third and fourth side surfaces 6C and 6D extend along the second direction Y, and face the first direction X. In detail, the second direction Y perpendicularly intersects the first direction X.

The semiconductor device 1 includes an n-type buffer region 7 formed in a surface layer portion of the second main surface 5. In this embodiment, the buffer region 7 is formed in the whole area of the surface layer portion of the second main surface 5. The buffer region 7 has an n-type impurity concentration exceeding the n-type impurity concentration of the semiconductor substrate 2. The n-type impurity concentration of the buffer region 7 may be not less than 1.0×10¹⁴ cm⁻³ and not more than 1.0×10¹⁸ cm⁻³.

The semiconductor device 1 includes a p-type well region 10 formed in a surface layer portion of the first main surface 4. The well region 10 has a p-type impurity concentration exceeding the n-type impurity concentration of the semiconductor substrate 2. The p-type impurity concentration of the well region 10 may be not less than 1.0×10¹⁵ cm⁻³ and not more than 1.0×10¹⁸ cm⁻³. The well region 10 is emitter-grounded.

The well region 10 is formed in a linear shape by which an inward portion of the first main surface 4 is defined from a plurality of directions at a distance inwardly from the side surfaces 6A to 6D in a plan view. In this embodiment, the well region 10 is formed in an endless shape surrounding the inward portion of the first main surface 4 in a plan view. In detail, the well region 10 is formed in an annular shape (in this embodiment, a quadrangular annular shape) having four sides parallel to the side surfaces 6A to 6D.

The well region 10 includes a pad well region 11 and a line well region 12. The pad well region 11 is a region into which a p-type impurity is introduced in a comparatively wide island shape. In this embodiment, the pad well region 11 is formed in a region closer to the first side surface 6A in the surface layer portion of the first main surface 4. In detail, the pad well region 11 is formed in a quadrangular shape in a region along a central portion of the first side surface 6A at a distance from the first side surface 6A toward the second side surface 6B in the surface layer portion of the first main surface 4.

The line well region 12 is a region into which a p-type impurity is introduced in a comparatively narrow linear shape. The line well region 12 has a width smaller than that of the pad well region 11, and is drawn out from the pad well region 11 in a linear shape. The line well region 12 extends along the side surfaces 6A to 6D in a plan view, and is formed in a linear shape by which the inward portion of the first main surface 4 is defined from a plurality of directions. In this embodiment, the line well region 12 is formed in an endless shape surrounding the inward portion of the first main surface 4 in a plan view. In detail, the well region 10 is formed in an annular shape (in this embodiment, a quadrangular annular shape) having four sides parallel to the side surfaces 6A to 6D.

The width W1 of the line well region 12 may be not less than 5 μm and not more than 100 μm. The width W1 is defined by a width in a direction perpendicular to a direction in which the line well region 12 extends. The width W1 may be not less than 5 μm and not more than 25 μm, not less than 25 μm and not more than 50 μm, not less than 50 μm and not more than 75 μm, or not less than 75 μm and not more than 100 μm.

The well region 10 demarcates an active region 13 and an outer region 14 in the semiconductor substrate 2. The active region 13 is defined by an inner peripheral edge of the well region 10 in a plan view. The outer region 14 is defined as a region between the side surfaces 6A to 6D and the inner peripheral edge of the well region 10 in a plan view.

The thickness of the well region 10 may be not less than 1 μm and not more than 20 μm. The thickness of the well region 10 may be not less than 1 μm and not more than 5 μm, not less than 5 μm and not more than 10 μm, not less than 10 μm and not more than 15 μm, or not less than 15 μm and not more than 20 μm.

The semiconductor device 1 includes an IGBT formed at the active region 13. The IGBT includes a p-type collector region 20 formed in the surface layer portion of the second main surface 5 and an FET structure 21 (Field Effect Transistor structure) formed in the first main surface 4.

In detail, the collector region 20 is formed in a surface layer portion closer to the second main surface 5 in the buffer region 7. The collector region 20 is formed in the whole area of the surface layer portion of the second main surface 5. The collector region 20 has a p-type impurity concentration exceeding the n-type impurity concentration of the semiconductor substrate 2. The p-type impurity concentration of the collector region 20 may be not less than 1.0×10¹⁵ cm⁻³ and not more than 1.0×10¹⁸ cm⁻³.

The FET structure 21 includes a p-type base region 22 formed in the surface layer portion of the first main surface 4. The base region 22 has a p-type impurity concentration exceeding the n-type impurity concentration of the semiconductor substrate 2. Preferably, the p-type impurity concentration of the base region 22 is less than the p-type impurity concentration of the well region 10. The p-type impurity concentration of the base region 22 may be not less than 1.0×10¹⁵ cm⁻³ and not more than 1.0×10¹⁷ cm⁻³.

The base region 22 is formed in the whole area of the active region 13, and is connected to the inner peripheral edge of the well region 10. The base region 22 has a thickness less than the thickness of the well region 10. Preferably, the thickness of the base region 22 is equal to or less than ½ of that of the well region 10. The thickness of the base region 22 may be not less than 1 μm and not more than 5 μm. The thickness of the base region 22 may be not less than 1 μm and not less than 2 μm, not less than 2 μm and not more than 3 μm, not less than 3 μm and not more than 4 μm, or not less than 4 μm and not more than 5 μm.

The FET structure 21 includes a plurality of trench gate structures 23 formed in the first main surface 4. The plurality of trench gate structures 23 are each formed in a linear shape extending along the first direction X, and are formed with intervals therebetween in the second direction Y. The plurality of trench gate structures 23 are formed in a stripe shape extending along the first direction X.

The plurality of trench gate structures 23 each include a gate trench 24, a gate insulation layer 25, and a gate electrode 26. The gate trench 24 is formed by digging the first main surface 4 down toward the second main surface 5. The gate trench 24 passes through the base region 22, and reaches the drift region 3. A bottom wall of the gate trench 24 is formed in a depth position between a bottom portion of the well region 10 and a bottom portion of the base region 22. A part, which is adjacent to the well region 10, of the gate trench 24 may be partially covered by the well region 10.

The gate insulation layer 25 is formed in a film shape along an inner wall of the gate trench 24. The gate insulation layer 25 includes at least one of a silicon oxide layer and a silicon nitride layer. In this embodiment, the gate insulation layer 25 is made of a silicon oxide layer. The gate electrode 26 is buried in the gate trench 24 with the gate insulation layer 25 between the gate electrode 26 and the gate trench 24. The gate electrode 26 includes conductive polysilicon.

The FET structure 21 includes a plurality of n-type emitter regions 27 formed in a surface layer portion of the base region 22. The emitter region 27 has an n-type impurity concentration exceeding the n-type impurity concentration of the semiconductor substrate 2. The n-type impurity concentration of the emitter region 27 may be not less than 1.0×10²⁶ cm⁻³ and not more than 5.0×10²⁰ cm⁻³.

The plurality of emitter regions 27 are each formed in a region between the plurality of trench gate structures 23 in the surface layer portion of the base region 22. The plurality of emitter regions 27 are formed in a belt shape extending along the trench gate structure 23. The plurality of emitter regions 27 face the gate electrode 26 with the gate insulation layer 25 between the emitter region 27 and the gate electrode 26. Bottom portions of the plurality of emitter regions 27 are each formed in a depth position between the first main surface 4 and the bottom portion of the base region 22. The plurality of emitter regions 27 define a channel of the IGBT with the bottom portion of the base region 22.

The FET structure 21 includes a plurality of emitter trenches 28 formed in the first main surface 4. The plurality of emitter trenches 28 are formed by digging the first main surface 4 down toward the second main surface 5 in a region between the plurality of trench gate structures 23. Each of the emitter trenches 28 is formed in a belt shape extending along the trench gate structure 23. Each of the emitter trenches 28 passes through the emitter region 27, and reaches the base region 22. A bottom wall of each of the emitter trenches 28 is formed in a depth position between the bottom portion of the emitter region 27 and the bottom portion of the base region 22.

The FET structure 21 includes a plurality of p-type contact regions 29 formed in the surface layer portion of the base region 22. The contact region 29 has a p-type impurity concentration exceeding the p-type impurity concentration of the base region 22. The p-type impurity concentration of the contact region 29 may be not less than 1.0×10¹⁶ cm⁻³ and not more than 1.0×10²⁰ cm⁻³.

In detail, each of the contact regions 29 is formed in a region along the bottom wall of the emitter trench 28 in the region between the plurality of trench gate structures 23. Each of the contact regions 29 may cover a sidewall of the emitter trench 28. Each of the contact regions 29 is formed at a distance from the bottom portion of the base region 22 toward the bottom wall of the emitter trench 28. Each of the contact regions 29 is formed in a belt shape extending along the trench gate structure 23.

In this embodiment, the FET structure 21 includes a plurality of n-type carrier storage regions 30 formed in the surface layer portion of the first main surface 4. The carrier storage region 30 has an n-type impurity concentration exceeding the n-type impurity concentration of the semiconductor substrate 2. The n-type impurity concentration of the carrier storage region 30 is less than the n-type impurity concentration of the emitter region 27. The n-type impurity concentration of the carrier storage region 30 may be not less than 1.0×10¹⁶ cm⁻³ and not more than 1.0×10¹⁸ cm⁻³.

Each of the carrier storage regions 30 is formed closer to the bottom wall of the trench gate structure 23 with respect to the base region 22 in the region between the plurality of trench gate structures 23. The bottom portion of each of the carrier storage regions 30 is formed in a depth position between the bottom portion of the base region 22 and the bottom wall of the trench gate structure 23. Each of the carrier storage regions 30 is formed in a belt shape extending along the trench gate structure 23 in a plan view. Each of the carrier storage regions 30 faces the gate electrode 26 with the gate insulation layer 25 between the carrier storage region 30 and the gate electrode 26.

The carrier storage region 30 prevents carriers (holes) supplied to the drift region 3 from being discharged to the base region 22. Hence, holes are accumulated in a region directly under the FET structure 21 in the drift region 3, and on-resistance is reduced. The carrier storage region 30 may be excluded if necessary.

The semiconductor device 1 includes a diode formed in the outer region 14. The diode includes an n-type cathode region 31 formed in the surface layer portion of the second main surface 5 and a p-type anode region 32 formed in the surface layer portion of the first main surface 4. The anode region 32 is formed by the well region 10. In other words, the diode includes the well region 10 serving as the anode region 32.

Referring to FIG. 4 to FIG. 7 (particularly FIG. 7), the cathode region 31 is formed in a mode in which a p-type impurity of the collector region 20 is offset by an n-type impurity in the surface layer portion of the second main surface 5. The cathode region 31 has an n-type impurity concentration exceeding the n-type impurity concentration of the semiconductor substrate 2. Preferably, the n-type impurity concentration of the cathode region 31 exceeds the n-type impurity concentration of the buffer region 7. The n-type impurity concentration of the cathode region 31 may be not less than 1.0×10¹⁶ cm⁻³ and not more than 5.0×10²⁰ cm⁻³.

The cathode region 31 is formed only at the outer region 14 in the surface layer portion of the second main surface 5. The cathode region 31 is not formed in a region directly under the FET structure 21 in the surface layer portion of the second main surface 5. The cathode region 31 is formed in a region directly under the well region 10 in the surface layer portion of the second main surface 5. Hence, the cathode region 31 faces the well region 10 with the drift region 3 between the cathode region 31 and the well region 10 with respect to the thickness direction (normal direction Z) of the semiconductor substrate 2.

The cathode region 31 is formed in a linear shape extending along the well region 10 in a plan view. The cathode region 31 defines the active region 13 from a plurality of directions in a plan view. In this embodiment, the cathode region 31 extends along the side surfaces 6A to 6D, and defines the active region 13 from four directions in a plan view. Preferably, the cathode region 31 is formed at a distance from the inner and outer peripheral edges of the well region 10 toward the inside of the well region 10 in a plan view. Preferably, the cathode region 31 is formed only in a region in which the cathode region 31 coincides with the well region 10 in a plan view.

In detail, the cathode region 31 is formed in a region directly under the line well region 12 in the surface layer portion of the second main surface 5, and exposes the pad well region 11. Preferably, the occupancy of the cathode region 31 in the region directly under the line well region 12 exceeds the occupancy of the collector region 20 in the region directly under the line well region 12.

On the other hand, preferably, the occupancy of the cathode region 31 in a region directly under the pad well region 11 is less than the occupancy of the collector region 20 in the region directly under the pad well region 11. In this embodiment, the cathode region 31 is formed only in the region directly under the line well region 12 in the surface layer portion of the second main surface 5, and is not formed in the region directly under the pad well region 11 in the surface layer portion of the second main surface 5.

In more detail, the cathode region 31 is formed in an ended linear shape that includes a first end portion 33 on one side, a second end portion 34 on the other side, and a line portion 35 extending through a region between the first end portion 33 and the second end portion 34. The first end portion 33, the second end portion 34, and the line portion 35 of the cathode region 31 are each formed in the region directly under the line well region 12.

The first end portion 33 is formed at a distance from the pad well region 11 toward one side (the third-side-surface-6C side) along the first direction X. The second end portion 34 is formed at a distance from the pad well region 11 toward the other side (the fourth-side-surface-6D side) along the first direction X. The second end portion 34 faces the first end portion 33 with the pad well region 11 between the second end portion 34 and the first end portion 33. The second end portion 34 forms a gap portion 36 that exposes the pad well region 11 in a region between the second end portion 34 and the first end portion 33. The line portion 35 extends along the line well region 12 in a plan view, and defines the active region 13 from a plurality of directions (in this embodiment, four directions).

The width W2 of the cathode region 31 may be not less than 5 μm and not more than 100 μm. The width W2 may be not less than 5 μm and not more than 25 μm, not less than 25 μm and not more than 50 μm, not less than 50 μm and not more than 75 μm, or not less than 75 μm and not more than 100 μm. Preferably, the width W2 is less than the width W1 of the line well region 12.

Preferably, the area ratio RS of the plane area of the cathode region 31 to the plane area of the active region 13 is not less than 1% and not more than 10%. The area ratio RS may be not less than 1% and not more than 2%, not less than 2% and not more than 4%, not less than 4% and not more than 6%, not less than 6% and not more than 8%, or not less than 8% and not more than 10%. Particularly preferably, the area ratio RS is not less than 1% and not more than 5%.

Referring to FIG. 2 and FIG. 8, the semiconductor device 1 includes an FL structure 40 (Field Limiting structure) formed in the surface layer portion of the first main surface 4 in the outer region 14. The FL structure 40 is formed in a region between the side surfaces 6A to 6D and the outer peripheral edge of the well region 10 at a distance from the side surfaces 6A to 6D and from the well region 10. The FL structure 40 is formed at a distance from the cathode region 31 toward a side opposite to the active region 13. The FL structure 40 does not coincide with the cathode region 31 in a plan view.

The FL structure 40 includes a single or a plurality of (in this embodiment, four) p-type FL regions 41A, 41B, 41C, and 41D (Field Limiting regions). The FL regions 41A to 41D are formed in an electrically floating state. The FL regions 41A to 41D have a p-type impurity concentration exceeding the n-type impurity concentration of the semiconductor substrate 2. Preferably, the p-type impurity concentration of the FL regions 41A to 41D exceeds the p-type impurity concentration of the base region 22. The p-type impurity concentration of the FL regions 41A to 41D may be not less than 1.0×10¹⁵ cm⁻³ and not more than 1.0×10¹⁸ cm⁻³.

The FL regions 41A to 41D are formed in this order in a direction away from the well region 10 with intervals between the FL regions 41A to 41D. In other words, the FL regions 41A to 41D are formed with intervals between the FL regions 41A to 41D from the cathode region 31 toward the peripheral edge (the side surfaces 6A to 6D) of the semiconductor substrate 2, and do not coincide with the cathode region 31 in a plan view. The FL regions 41A to 41D extend along the well region 10 in a linear shape in a plan view. In detail, the FL regions 41A to 41D are formed in an annular shape (quadrangular annular shape) surrounding the well region 10 in a plan view. Hence, the FL regions 41A to 41D are formed as an FLR region (Field Limiting Ring region).

The FL regions 41A to 41D have a thickness exceeding the thickness of the base region 22. Bottom portions of the FL regions 41A to 41D are placed in a region on the second-main surface-5 side with respect to the bottom portion of the base region 22. Preferably, the FL regions 41A to 41D are each formed with a predetermined thickness.

The thickness of the FL regions 41A to 41D may be not less than 1 μm and not more than 20 μm. The thickness of the FL regions 41A to 41D may be not less than 1 μm and not more than 5 μm, not less than 5 μm and not more than 10 μm, not less than 10 μm and not more than 15 μm, or not less than 15 μm and not more than 20 μm. Preferably, the thickness of the FL regions 41A to 41D is equal to the thickness of the well region 10.

The width of the FL regions 41A to 41D may be not less than 5 μm and not more than 50 μm. The width of the FL regions 41A to 41D may be not less than 5 μm and not more than 10 μm, not less than 10 μm and not more than 20 μm, not less than 20 μm and not more than 30 μm, not less than 30 μm and not more than 40 μm, or not less than 40 μm and not more than 50 μm. Preferably, the width of the FL regions 41A to 41D is not less than 10 μm and not more than 30 μm.

The distance between the FL regions 41A to 41D adjoining each other may be not less than 5 μm and not more than 50 μm. The distance between the FL regions 41A to 41D may be not less than 5 μm and not more than 10 μm, not less than 10 μm and not more than 20 μm, not less than 20 μm and not more than 30 μm, not less than 30 μm and not more than 40 μm, or not less than 40 μm and not more than 50 μm. The distance between the FL regions 41A to 41D may become longer in proportion to progression in a direction away from the well region 10.

The distance between the well region 10 and the FL region 41A may be not less than 5 μm and not more than 50 μm. The distance between the well region 10 and the FL region 41A may be not less than 5 μm and not more than 10 μm, not less than 10 μm and not more than 20 μm, not less than 20 μm and not more than 30 μm, not less than 30 μm and not more than 40 μm, or not less than 40 μm and not more than 50 μm.

The semiconductor device 1 includes an n-type CS region 42 (Channel Stop region) formed in the surface layer portion of the first main surface 4 in the outer region 14. The CS region 42 has an n-type impurity concentration exceeding the n-type impurity concentration of the semiconductor substrate 2. The n-type impurity concentration of the CS region 42 may be not less than 1.0×10¹⁵ cm⁻³ and not more than 1.0×10¹⁸ cm⁻³.

The CS region 42 is formed in a region between the side surfaces 6A to 6D and the FL structure 40 at a distance from the FL structure 40. The CS region 42 may be exposed from the side surfaces 6A to 6D. The CS region 42 extends in a linear shape along the FL structure 40 in a plan view. In detail, the CS region 42 is formed in an annular shape (quadrangular annular shape) surrounding the FL structure 40 in a plan view. The CS region 42 is formed in an electrically floating state.

The width of the CS region 42 may be not less than 50 μm and not more than 150 μm. The width of the CS region 42 is a width in a direction perpendicular to a direction in which the CS region 42 extends. The width of the CS region 42 may be not less than 50 μm and not more than 75 μm, not less than 75 μm and not more than 100 μm, not less than 100 μm and not more than 125 μm, or not less than 125 μm and not more than 150 μm.

The semiconductor device 1 includes an insulation layer 50 that covers the first main surface 4. The insulation layer 50 has a layered structure including a first insulation layer 51 and a second insulation layer 52. The first insulation layer 51 covers substantially the whole area of the first main surface 4. In detail, the first insulation layer 51 selectively covers the FET structure 21 in the active region 13, and selectively covers the well region 10, the FL structure 40, and the CS region 42 in the outer region 14. The first insulation layer 51 is continuous with the gate insulation layer 25 in the active region 13. The second insulation layer 52 covers substantially the whole area of the first insulation layer 51.

The first insulation layer 51 may have a layered structure in which a plurality of insulation layers are stacked together, or may have a single-layer structure consisting of the single insulation layer 50. The first insulation layer 51 may include at least one of a silicon oxide layer and a silicon nitride layer. The first insulation layer 51 may have a layered structure in which a silicon oxide layer and a silicon nitride layer are stacked together in arbitrary order. The first insulation layer 51 may have a single-layer structure consisting of a silicon oxide layer or a silicon nitride layer.

The second insulation layer 52 may have a layered structure in which a plurality of insulation layers are stacked together, or may have a single-layer structure consisting of the single insulation layer 50. The second insulation layer 52 may include at least one of a silicon oxide layer and a silicon nitride layer. The second insulation layer 52 may have a layered structure in which a silicon oxide layer and a silicon nitride layer are stacked together in arbitrary order. The second insulation layer 52 may have a single-layer structure consisting of a silicon oxide layer or a silicon nitride layer.

Referring to FIG. 4 to FIG. 6, the semiconductor device 1 includes a gate wiring layer 53 buried in a part, which covers the well region 10, of the insulation layer 50. In detail, the gate wiring layer 53 is formed on a part, which covers the well region 10, of the first insulation layer 51. The gate wiring layer 53 faces the well region 10 with the first insulation layer 51 between the gate wiring layer 53 and the well region 10, and is covered by the second insulation layer 52. Preferably, the gate wiring layer 53 is made of the same electrode material as the gate electrode 26. In this embodiment, the gate wiring layer 53 is made of conductive polysilicon.

The gate wiring layer 53 includes a line wiring portion 54 and a plurality of connection wiring portions 55. The line wiring portion 54 extends in a linear shape along the well region 10 in a plan view. The line wiring portion 54 includes its part that covers the pad well region 11 and its part that covers the line well region 12. The part covering the pad well region 11 of the line wiring portion 54 does not coincide with the cathode region 31 in a plan view. The part covering the line well region 12 of the line wiring portion 54 coincides with the cathode region 31 in a plan view.

Preferably, the line wiring portion 54 defines the active region 13 from a plurality of directions in a plan view. In this embodiment, the line wiring portion 54 extends along the side surfaces 6A to 6D in a plan view, and defines the active region 13 from four directions. The line wiring portion 54 may be formed in an endless shape (annular shape) or may be formed in an ended shape.

The line wiring portion 54 has a width less than the width W1 of the line well region 12. The line wiring portion 54 is formed at a distance from the inner and outer peripheral edges of the well region 10 toward the inside of the well region 10. Hence, the whole area of the line wiring portion 54 faces the well region 10 with the first insulation layer 51 between the line wiring portion 54 and the well region 10.

The width of the line wiring portion 54 is arbitrary. The line wiring portion 54 may be formed with a uniform width. The width of the part covering the line well region 12 of the line wiring portion 54 may be less than the width of the part covering the pad well region 11 of the line wiring portion 54.

The plurality of connection wiring portions 55 are each drawn out from the line wiring portion 54 toward both end portions of the plurality of trench gate structures 23 (see FIG. 5). In detail, the plurality of connection wiring portions 55 are drawn out from a part, which extends along the third side surface 6C (the fourth side surface 6D), of the line wiring portion 54 toward the plurality of gate electrodes 26. The plurality of connection wiring portions 55 are drawn out in one-to-one correspondence with respect to the plurality of gate electrodes 26, and are each connected to a corresponding one of the gate electrodes 26. Hence, the gate wiring layer 53 is electrically connected to the gate electrode 26.

The semiconductor device 1 includes a plurality of emitter openings 61 formed in the insulation layer 50. The emitter openings 61 expose the plurality of emitter trenches 28, respectively, in one-to-one correspondence in the active region 13. The plurality of emitter openings 61 communicate with the plurality of emitter trenches 28, respectively.

The semiconductor device 1 includes a single or a plurality of (in this embodiment, a plurality of) first well openings 62 formed in the insulation layer 50. The plurality of first well openings 62 selectively expose the inner peripheral edge of the well region 10 in the outer region 14. In this embodiment, the plurality of first well openings 62 are formed with intervals between the first well openings 62 along the inner peripheral edge of the well region 10 so as to surround the active region 13. The plurality of first well openings 62 may be each formed in a linear shape extending along the inner peripheral edge of the well region 10.

The semiconductor device 1 includes a single or a plurality of (in this embodiment, one) second well openings 63 formed in the insulation layer 50. The second well opening 63 selectively exposes the outer peripheral edge of the well region 10 in the outer region 14. In this embodiment, the second well opening 63 is formed in a linear shape extending along the outer peripheral edge of the well region 10 so as to surround the active region 13. In this embodiment, the second well opening 63 is formed in an annular shape (quadrangular annular shape) that exposes the outer peripheral edge of the well region 10. The second well opening 63 may be formed in an endless shape, or may be formed in an ended shape.

The semiconductor device 1 includes a plurality of FL openings 64 formed in the insulation layer 50. The plurality of FL openings 64 selectively expose a plurality of FL regions 41A to 41D, respectively, in one-to-one correspondence in the outer region 14. The plurality of FL openings 64 are formed in a linear shape extending along the plurality of FL regions 41A to 41D, respectively. In this embodiment, the plurality of FL openings 64 are formed in an annular shape (quadrangular annular shape) exposing the plurality of FL regions 41A to 41D. The plurality of FL openings 64 may be formed in an endless shape, or may be formed in an ended shape.

The semiconductor device 1 includes a single or a plurality of (in this embodiment, one) CS openings 65 formed in the insulation layer 50. The CS opening 65 selectively exposes the CS region 42 in the outer region 14. The CS opening 65 is formed in a linear shape extending along the CS region 42. In this embodiment, the CS opening 65 is formed in an annular shape (quadrangular annular shape) exposing the CS region 42, and communicates with the side surfaces 6A to 6D. The CS opening 65 may be formed in an endless shape, or may be formed in an ended shape.

The semiconductor device 1 includes a single or a plurality of (in this embodiment, one) gate openings 66 formed in the insulation layer 50. The gate opening 66 selectively exposes the gate wiring layer 53 in the outer region 14. The gate opening 66 is formed in a linear shape extending along the gate wiring layer 53. The gate opening 66 may be formed in an endless shape, or may be formed in an ended shape.

Referring to FIG. 4 to FIG. 6, the semiconductor device 1 includes a plurality of emitter plug electrodes 67 buried in the plurality of emitter trenches 28 through the plurality of emitter openings 61, respectively. The plurality of emitter plug electrodes 67 are each electrically connected to the emitter region 27 and to the contact region 29 in the emitter trench 28 corresponding thereto. The plurality of emitter plug electrodes 67 each have a layered structure including a barrier electrode 68 and a principal electrode 69.

The barrier electrode 68 is formed in a film shape along an inner wall of the emitter trench 28 and an inner wall of the emitter opening 61. The barrier electrode 68 may have a single-layer structure including a titanium layer or a titanium nitride layer. The barrier electrode 68 may have a layered structure including a titanium layer and a titanium nitride layer in arbitrary order. The principal electrode 69 is embedded in the emitter trench 28 and in the emitter opening with the barrier electrode 68 between the principal electrode 69 and both the emitter trench 28 and the emitter opening 61. The principal electrode 69 may include tungsten.

Referring to FIG. 1 to FIG. 8, the semiconductor device 1 includes a gate main surface electrode 71 formed on the first main surface 4. In detail, the gate main surface electrode 71 is formed on a part, which covers the well region 10, of the insulation layer 50. The gate main surface electrode 71 enters the gate opening 66 from above the insulation layer 50, and is electrically connected to the gate wiring layer 53. In more detail, the gate main surface electrode 71 integrally includes a gate pad electrode 72 and a gate finger electrode 73.

The gate pad electrode 72 is an external terminal portion that is externally connected to a lead wire (for example, bonding wire) or the like. The gate pad electrode 72 is formed on apart, which covers the pad well region 11, of the insulation layer 50. Hence, the gate pad electrode 72 faces the pad well region 11 with the insulation layer 50 between the gate pad electrode 72 and the pad well region 11. The gate pad electrode 72 does not coincide with the cathode region 31 in a plan view. The thus formed structure makes it possible to restrain electric-current concentration that occurs in the semiconductor substrate 2 resulting from the disposition of both the gate pad electrode 72 and the cathode region 31.

Preferably, the gate pad electrode 72 covers the whole area of the pad well region 11. The gate pad electrode 72 is formed in a quadrangular shape matching the pad well region 11 in a plan view. The planar shape of the gate pad electrode 72 is arbitrary. The gate pad electrode 72 enters the gate opening 66 from above the insulation layer 50, and is electrically connected to the gate wiring layer 53.

The gate finger electrode 73 is drawn out from the gate pad electrode 72 onto a part, which covers the line well region 12, of the insulation layer 50. Hence, the gate finger electrode 73 faces the line well region 12 with the insulation layer 50 between the gate finger electrode 73 and the line well region 12. The gate finger electrode 73 coincides with the cathode region 31 in a plan view. The gate finger electrode 73 extends in a linear shape along the line well region 12 in a plan view, and defines the active region 13 from a plurality of directions.

In this embodiment, the gate finger electrode 73 extends along the side surfaces 6A to 6D in a plan view, and defines the active region 13 from four directions. The gate finger electrode 73 is formed in an ended linear shape having first and second end portions 74 and 75. In this embodiment, the first and second end portions 74 and 75 are formed in a region along the second side surface 6B. A region between the first and second end portions 74 and 75 faces the gate pad electrode 72 in the second direction Y. Positions of the first and second end portions 74 and 75 are arbitrary. The gate finger electrode 73 enters the gate opening 66 from above the insulation layer 50, and is electrically connected to the gate wiring layer 53.

The semiconductor device 1 includes an emitter main surface electrode 76 formed on the first main surface 4 at a distance from the gate main surface electrode 71. The emitter main surface electrode 76 serves also as an anode electrode of the diode. The emitter main surface electrode 76 is formed on a region outside the gate main surface electrode 71 in the insulation layer 50.

The emitter main surface electrode 76 is electrically connected to the plurality of emitter plug electrodes 67. Additionally, the emitter main surface electrode 76 enters the first and second well openings 62 and 63 from above the insulation layer 50, and is electrically connected to the well region 10. In detail, the emitter main surface electrode 76 integrally includes an emitter pad electrode 77 and an emitter finger electrode 78.

The emitter pad electrode 77 is an external terminal portion that is externally connected to a lead wire (for example, bonding wire) or the like. The emitter pad electrode 77 is formed on a part, which covers the active region 13, of the insulation layer 50, and faces the FET structure 21 with the insulation layer 50 between the emitter pad electrode 77 and the FET structure 21. The emitter pad electrode 77 is formed in a polygonal shape along an inner edge of the gate pad electrode 72 and an inner edge of the gate finger electrode 73. The emitter pad electrode 77 is electrically connected to the plurality of emitter plug electrodes 67.

The emitter pad electrode 77 has a peripheral edge portion 79 covering the inner peripheral edge of the well region 10. The peripheral edge portion 79 of the emitter pad electrode 77 coincides with the cathode region 31 in a plan view. The peripheral edge portion 79 of the emitter pad electrode 77 may be formed at a distance from the cathode region 31 toward the active region 13 in a plan view. The peripheral edge portion 79 of the emitter pad electrode 77 enters the first well opening 62 from above the insulation layer 50, and is electrically connected to the inner peripheral edge of the well region 10.

The emitter finger electrode 78 crosses a region between the first and second end portions 74 and 75 of the gate finger electrode 73 on the insulation layer 50, and is drawn out to a region outside the gate finger electrode 73. The emitter finger electrode 78 is formed on a part, which covers the outer peripheral edge of the well region 10, of the insulation layer 50, and extends in a linear shape along the well region 10.

The emitter finger electrode 78 defines the active region 13 from a plurality of directions in a plan view. In this embodiment, the emitter finger electrode 78 extends along the side surfaces 6A to 6D in a plan view, and defines the active region 13 from four directions. In detail, the emitter finger electrode 78 is formed in an endless shape surrounding the gate finger electrode 73. The emitter finger electrode 78 may be formed in an ended shape.

The emitter finger electrode 78 includes its part covering the pad well region 11 and its part covering the line well region 12. The part, which covers the pad well region 11, of the emitter finger electrode 78 does not coincide with the cathode region 31 in a plan view. The part, which covers the line well region 12, of the emitter finger electrode 78 coincides with the cathode region 31 in a plan view. The emitter finger electrode 78 may be formed at a distance from the cathode region 31 toward the side surfaces 6A to 6D in a plan view. The emitter finger electrode 78 enters the second well opening 63 from above the insulation layer 50, and is electrically connected to the outer peripheral edge of the well region 10.

Referring to FIG. 1 and FIG. 8, the semiconductor device 1 includes a plurality of (in this embodiment, four) field electrodes 80A to 80D formed on the first main surface 4 in the outer region 14. In detail, the field electrodes 80A to 80D are each formed on the insulation layer 50.

The plurality of field electrodes 80A to 80D are formed in one-to-one correspondence with respect to the plurality of FL regions 41A to 41D. The plurality of field electrodes 80A to 80D are formed in a linear shape extending along the FL regions 41A to 41D corresponding thereto, respectively. In this embodiment, the plurality of field electrodes 80A to 80D are formed in an annular shape extending along the FL regions 41A to 41D corresponding thereto, respectively. The plurality of field electrodes 80A to 80D enter the FL openings 64 corresponding thereto from above the insulation layer 50, and are electrically connected to the FL regions 41A to 41D corresponding thereto, respectively. The field electrodes 80A to 80D are formed in an electrically floating state.

The outermost field electrode 80D may include a plate portion 81 drawn out toward the side surfaces 6A to 6D. The width of the field electrode 80D including the plate portion 81 may be not less than 20 μm and not more than 100 μm. The width of the field electrode 80D is a width in a direction perpendicular to a direction in which the field electrode 80D extends. The width of the field electrode 80D may be not less than 20 μm and not more than 40 μm, not less than 40 μm and not more than 60 μm, not less than 60 μm and not more than 80 μm, or not less than 80 μm and not more than 100 μm.

Referring to FIG. 1 and FIG. 8, the semiconductor device 1 includes an equipotential electrode 82 formed on the first main surface 4 in the outer region 14. In detail, the equipotential electrode 82 is formed on the insulation layer 50. The equipotential electrode 82 is formed in a linear shape extending along the CS region 42. In this embodiment, the equipotential electrode 82 is formed in an annular shape extending along the CS region 42.

The equipotential electrode 82 enters the CS opening 65 corresponding thereto from above the insulation layer 50, and is electrically connected to the CS region 42. An outer peripheral edge of the equipotential electrode 82 is formed at a distance from the side surfaces 6A to 6D toward the inside (the FL-structure-40 side) of the semiconductor substrate 2, and exposes a peripheral edge portion of the first main surface 4 (the CS region 42). The equipotential electrode 82 is electrically formed in a floating state.

The insulation distance between the equipotential electrode 82 and the outermost field electrode 80D may be not less than 20 μm and not more than 100 μm. The insulation distance may be not less than 20 μm and not more than 40 μm, not less than 40 μm and not more than 60 μm, not less than 60 μm and not more than 80 μm, or not less than 80 μm and not more than 100 μm.

The gate main surface electrode 71, the emitter main surface electrode 76, the field electrodes 80A to 80D, and the equipotential electrode 82 each include a barrier electrode 83 and a principal electrode 84 that are stacked together in this order from the first-main surface-4 side.

The barrier electrode 83 is formed in a film shape on the insulation layer 50 (the first main surface 4). The barrier electrode 83 may have a single-layer structure including a titanium layer or a titanium nitride layer. The barrier electrode 83 may have a layered structure including a titanium layer and a titanium nitride layer in arbitrary order. The principal electrode 84 is formed in a film shape on the barrier electrode 83. The principal electrode 84 may include at least one among a pure Cu layer (a Cu layer whose purity is 99% or more), a pure Al layer (an Al layer whose purity is 99% or more), an AlSi alloy layer, an AlCu alloy layer, and an AlSiCu alloy layer.

The semiconductor device 1 includes a collector electrode 85 connected to the second main surface 5. The collector electrode 85 serves also as a cathode electrode of the diode. The collector electrode 85 covers the whole area of the second main surface 5, and is electrically connected to the collector region 20 and to the cathode region 31.

The collector electrode 85 includes at least one among a Ti layer, an Ni layer, a Pd layer, an Au layer, and an Ag layer. The collector electrode 85 may have a layered structure in which at least two among a Ti layer, an Ni layer, a Pd layer, an Au layer, and an Ag layer are stacked together in arbitrary order. The collector electrode 85 may have a single-layer structure consisting of a Ti layer, an Ni layer, a Pd layer, an Au layer, and an Ag layer. Preferably, the collector electrode 85 includes a Ti layer serving as an ohmic electrode. In this embodiment, the collector electrode 85 has a layered structure in which a Ti layer, an Ni layer, a Pd layer, an Au layer, and an Ag layer are stacked together in this order from the second-main surface-5 side.

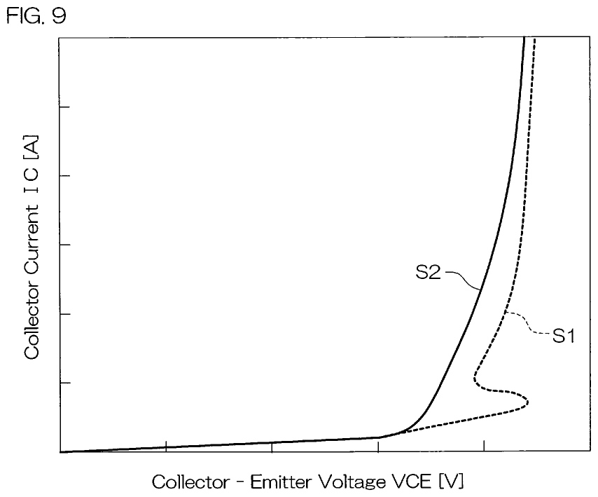

FIG. 9 is a graph showing a current-voltage characteristic. In FIG. 9, the ordinate axis represents a collector current IC [A], and the abscissa axis represents a collector emitter voltage VCE [V].

A first characteristic 51 (see the broken line) and a second characteristic S2 (see the solid line) are shown in FIG. 9. The first characteristic 51 shows a current-voltage characteristic of a semiconductor device according to a comparative example. The second characteristic S2 shows a current-voltage characteristic of the semiconductor device 1. The semiconductor device according to the comparative example includes the cathode region 31 formed in the region directly under the FET structure 21 in the surface layer portion of the second main surface 5.

The first characteristic 51 has a snapback waveform in which the collector emitter voltage VCE increases, and then rapidly decreases, and reaches a low impedance region. On the other hand, the second characteristic S2 does not have such a snapback waveform as the first characteristic 51.

In the semiconductor device according to the comparative example, the cathode region 31 is formed in the region directly under the FET structure 21 in the surface layer portion of the second main surface 5. Therefore, when the IGBT performs a start-up operation (when the collector emitter voltage VCE rises), electrons injected from the emitter region 27 flow into the cathode region 31. As a result, a snapback phenomenon occurs, and switching characteristics are lowered.

On the other hand, in the semiconductor device 1, the cathode region 31 is not formed in the region directly under the FET structure 21 in the surface layer portion of the second main surface 5. The cathode region 31 according to the semiconductor device 1 is formed only at the outer region 14. In detail, the cathode region 31 according to the semiconductor device 1 is formed only in the region directly under the well region 10.

The thus formed structure makes it possible to restrain the flow of electrons injected from the emitter region 27 into the cathode region 31 when the IGBT performs a start-up operation (when the collector emitter voltage VCE rises). As a result, it is possible to restrain a deterioration in switching characteristics caused by the snapback phenomenon.

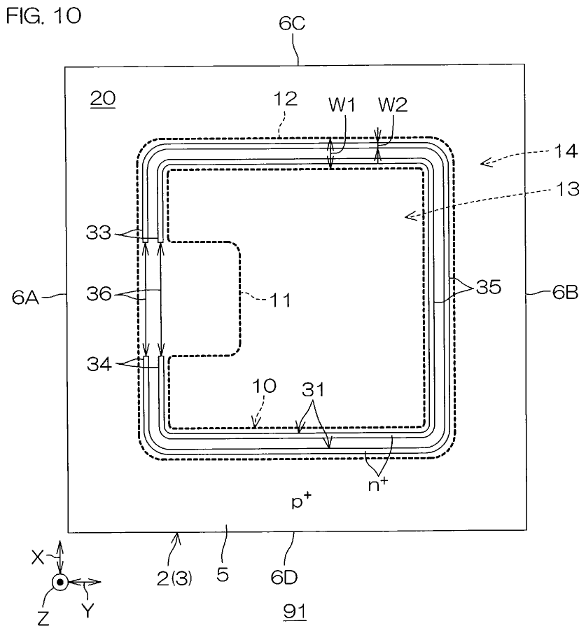

FIG. 10 corresponds to FIG. 7, and is a plan view showing a structure of a second main surface 5 of a semiconductor device 91 according to a second preferred embodiment of the present invention. The same reference sign is hereinafter given to a constituent equivalent to each constituent described with respect to the semiconductor device 1, and a description of the constituent is omitted.

Referring to FIG. 10, the semiconductor device 91 includes a plurality of (two or more) cathode regions 31 formed only at the outer region 14 in the surface layer portion of the second main surface 5. The plurality of cathode regions 31 are formed only in the region overlapping with the well region 10 in the surface layer portion of the second main surface 5 in the same way as in the first preferred embodiment.

The plurality of cathode regions 31 extend in a linear shape along the well region 10, and are formed at a distance from each other in a direction away from the active region 13. The plurality of cathode regions 31 each include the first end portion 33, the second end portion 34 on the other side, and the line portion 35 extending through the region between the first end portion 33 and the second end portion 34 in the same way as the cathode region 31 according to the first preferred embodiment.

Preferably, the area ratio RS of the plane area (total plane area) of the plurality of cathode regions 31 to the plane area of the active region 13 is not less than 1% and not more than 10%. The area ratio RS may be not less than 1% and not more than 2%, not less than 2% and not more than 4%, not less than 4% and not more than 6%, not less than 6% and not more than 8%, or not less than 8% and not more than 10%. Particularly preferably, the area ratio RS is not less than 1% and not more than 5%.

As described above, the semiconductor device 91 is likewise enabled to fulfill the same effect as the effect described with respect to the semiconductor device 1.

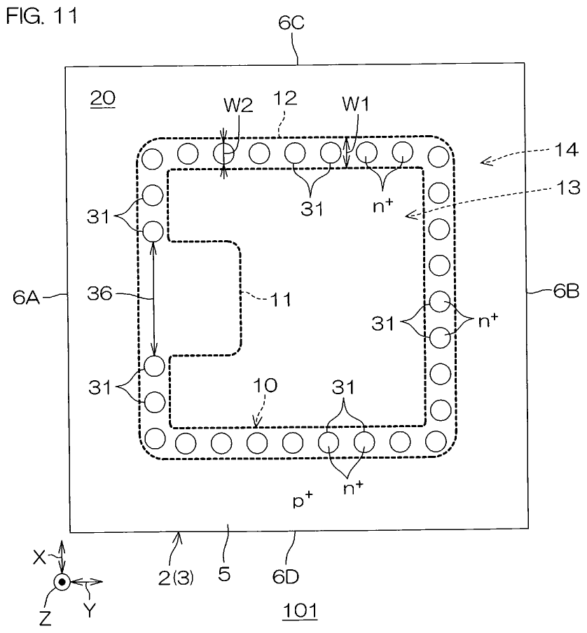

FIG. 11 corresponds to FIG. 7, and is a plan view showing a structure of a second main surface 5 of a semiconductor device 101 according to a third preferred embodiment of the present invention. The same reference sign is hereinafter given to a constituent equivalent to each constituent described with respect to the semiconductor device 1, and a description of the constituent is omitted.

Referring to FIG. 11, the semiconductor device 101 includes a plurality of cathode regions 31 formed only at the outer region 14 in the surface layer portion of the second main surface 5. The plurality of cathode regions 31 are formed only in the region overlapping with the well region 10 in the surface layer portion of the second main surface 5 in the same way as in the first preferred embodiment.

The plurality of cathode regions 31 are formed at a distance from each other along the well region 10 in a plan view. In this embodiment, the plurality of cathode regions 31 are each formed in a circular shape in a plan view. The planar shape of the plurality of cathode regions 31 is arbitrary. The plurality of cathode regions 31 may be formed in a linear shape, in a polygonal shape, or in an elliptical shape.

In detail, the plurality of cathode regions 31 are formed in the region directly under the line well region 12 in the surface layer portion of the second main surface 5, and expose the pad well region 11. Preferably, the occupancy of the plurality of cathode regions 31 in the region directly under the line well region 12 exceeds the occupancy of the plurality of collector regions 20 in the region directly under the line well region 12.

On the other hand, preferably, the occupancy of the plurality of cathode regions 31 in the region directly under the pad well region 11 is less than the occupancy of the collector region 20 in the region directly under the pad well region 11. In this embodiment, the plurality of cathode regions 31 are formed only in the region directly under the line well region 12 in the surface layer portion of the second main surface 5, and are not formed in the region directly under the pad well region 11 in the surface layer portion of the second main surface 5.

In other words, the plurality of cathode regions 31 are formed at a distance from the pad well region 11 toward one side (the third-side-surface-6C side) and toward the other side (the fourth-side-surface-6D side) in the first direction X. The plurality of cathode regions 31 face each other in the first direction X with the pad well region 11 between the cathode regions 31, and form a gap portion 36 by which the pad well region 11 is exposed.

Preferably, the area ratio RS of the plane area of the plurality of cathode regions 31 (total plane area) to the plane area of the active region 13 is not less than 1% and not more than 10%. The area ratio RS may be not less than 1% and not more than 2%, not less than 2% and not more than 4%, not less than 4% and not more than 6%, not less than 6% and not more than 8%, or not less than 8% and not more than 10%. Particularly preferably, the area ratio RS is not less than 1% and not more than 5%.

As described above, the semiconductor device 101 is likewise enabled to fulfill the same effect as the effect described with respect to the semiconductor device 1.

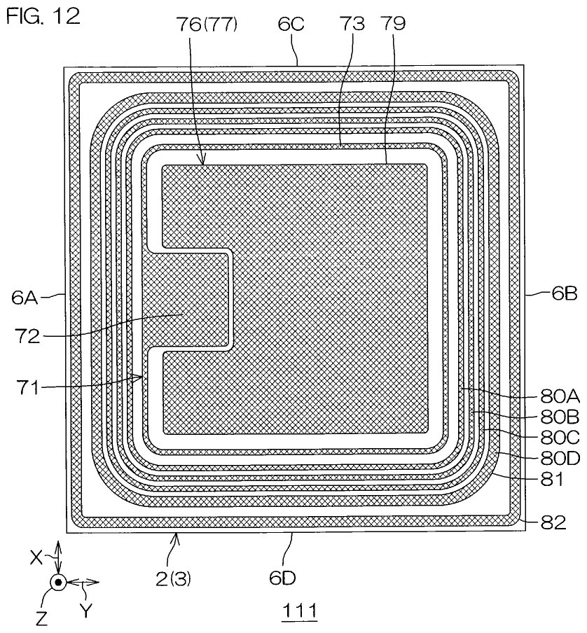

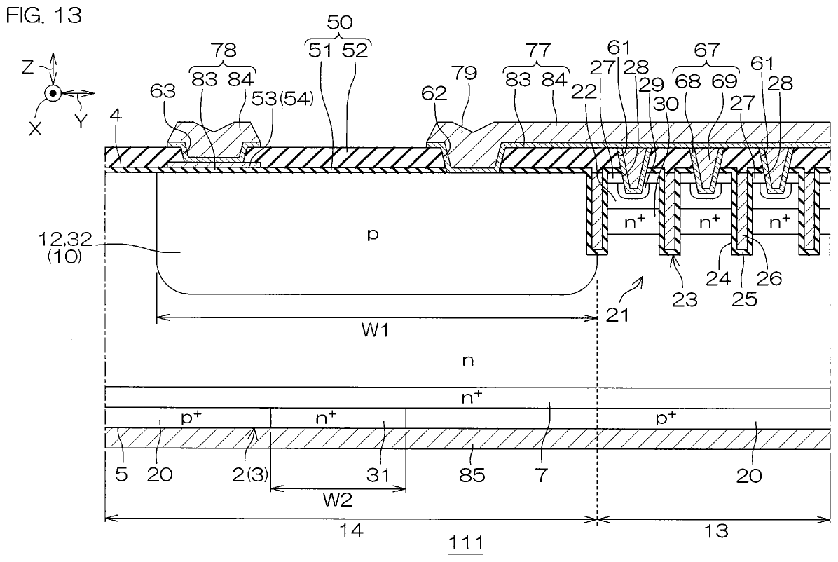

FIG. 12 is a plan view showing a semiconductor device 111 according to a fourth preferred embodiment of the present invention. FIG. 13 is an enlarged view of a main portion of a first main surface 4 of the semiconductor device 111 shown in FIG. 12. FIG. 12 corresponds to FIG. 1 mentioned above, and FIG. 13 corresponds to FIG. 4 mentioned above. The same reference sign is hereinafter given to a constituent equivalent to each constituent described with respect to the semiconductor device 1, and a description of the constituent is omitted.

Referring to FIG. 12 and FIG. 13, the emitter main surface electrode 76 according to the semiconductor device 111 does not have the emitter finger electrode 78. In this embodiment, the gate finger electrode 73 according to the semiconductor device 111 is formed in an endless shape surrounding the active region 13 in a plan view. The gate finger electrode 73 may be formed in an ended shape in the same way as in the first preferred embodiment.

The gate finger electrode 73 faces the outer peripheral edge of the well region 10 with the insulation layer 50 between the gate finger electrode 73 and the well region 10. In this embodiment, the gate finger electrode 73 is formed at a distance from the cathode region 31 toward the outer peripheral edge of the well region 10 in a plan view, and exposes the whole area of the cathode region 31. The gate finger electrode 73 does not coincide with the cathode region 31 in a plan view. The thus formed structure makes it possible to restrain electric-current concentration that occurs in the semiconductor substrate 2 resulting from the disposition of both the gate finger electrode 73 and the cathode region 31.

The gate finger electrode 73 may be formed at a distance from the outer peripheral edge of the well region 10 toward the side surfaces 6A to 6D (the FL structure 40) in a plan view, and may expose the whole area of the well region 10. Likewise, the thus formed structure makes it possible to restrain electric-current concentration that occurs in the semiconductor substrate 2 resulting from the disposition of both the gate finger electrode 73 and the cathode region 31.

The gate finger electrode 73 may be formed so as to overlap a part of the cathode region 31 in a plan view. In this case, preferably, the gate finger electrode 73 is formed such that an exposed portion of the cathode region 31 goes over a covered portion of the cathode region 31. Likewise, the thus formed structure makes it possible to restrain electric-current concentration that occurs in the semiconductor substrate 2 resulting from the disposition of both the gate finger electrode 73 and the cathode region 31.

As described above, the semiconductor device 111 is likewise enabled to fulfill the same effect as the effect described with respect to the semiconductor device 1. The structure of the semiconductor device 111 can also be incorporated into the second and third preferred embodiments.

The embodiment of the present invention can be carried out in other modes.

As described in each of the aforementioned embodiments, the emitter main surface electrode 76 is connected to the emitter region 27 and to the contact region 29 through the plurality of emitter plug electrodes 67. However, a mode may be employed in which the emitter plug electrode 67 is excluded and in which the emitter main surface electrode 76 enters both the emitter trench 28 and the emitter opening 61, and is directly connected to the emitter region 27 and to the contact region 29.

In the aforementioned preferred embodiments, a structure may be employed in which the conductivity type of each of the semiconductor parts is reversed. In other words, the p-type part may be changed to an n-type, and the n-type part may be changed to a p-type.

The semiconductor devices 1, 91, 101, and 111 according to the first to fourth preferred embodiments are each enabled to be incorporated into an inverter circuit, a power factor improvement circuit, a resonant circuit, etc. However, preferably, in an RC-IGBT incorporated in the inverter circuit, the area ratio RS of the plane area of the cathode region 31 to the plane area of the active region 13 is set at a value exceeding 10% (for example, not less than 15% and not more than 50%) because of the property of the diode used as a reflux diode. In this case, preferably, the cathode region 31 is formed in the region directly under the FET structure 21, and a part or all of the base region 22 is used as the anode region 32.

On the other hand, in an RC-IGBT incorporated in the power factor improvement circuit, the resonant circuit, or the like, a comparatively large area ratio RS is not required because of the property of the diode used as a protection device, and the cathode region 31 can avoid being formed in the region directly under the FET structure 21. In other words, the area ratio RS may be, for example, not less than 1% and not more than 10% (preferably, not less than 1% and not more than 5%). In this case, the restraint of a snapback phenomenon makes it possible to appropriately improve a protective function performed by the diode.

As thus described, the RC-IGBT incorporated in the inverter circuit has a design concept differing from that of the RC-IGBT incorporated in the power factor improvement circuit, the resonant circuit, etc. Therefore, preferably, the semiconductor devices 1, 91, 101, 111 are each incorporated into an electrical circuit in which the diode is used as a protective device, such as a power factor improvement circuit or a resonant circuit (particularly, an electrical circuit in which the diode is not positively used as a reflux diode).

Examples of features extracted from this description and the drawings are shown below. The following [A1] to [A17] provide a semiconductor device capable of restraining a deterioration in switching characteristics that is caused by a snapback phenomenon.

[A1] A semiconductor device comprising: a first-conductivity-type semiconductor substrate that has a first main surface on one side and a second main surface on another side; a second-conductivity-type well region that is formed in a surface layer portion of the first main surface and that demarcates an active region and an outer region 14 in the semiconductor substrate; an IGBT including a second-conductivity-type collector region formed at the active region in a surface layer portion of the second main surface and an FET structure formed at the active region in the first main surface; and a diode that includes a first-conductivity-type cathode region formed only at the outer region in the surface layer portion of the second main surface and that has the well region serving as an anode region. According to this semiconductor device, it is possible to restrain a deterioration in switching characteristics that is caused by a snapback phenomenon.

[A2] The semiconductor device according to A1, wherein the collector region is formed in a whole area of the surface layer portion of the second main surface, and the cathode region is formed in a mode in which a second-conductivity-type impurity of the collector region is offset by a first-conductivity-type impurity.

[A3] The semiconductor device according to A1 or A2, wherein the cathode region is formed in a region overlapping with the well region.

[A4] The semiconductor device according to any one of A1 to A3, wherein the cathode region is formed only in a region overlapping with the well region.

[A5] The semiconductor device according to any one of A1 to A4, wherein the cathode region has a plane area that is not less than 1% and not more than 10% of a plane area of the active region.

[A6] The semiconductor device according to any one of A1 to A5, wherein the cathode region has a plane area that is not less than 1% and not more than 5% of a plane area of the active region.

[A7] The semiconductor device according to any one of A1 to A6, wherein the well region extends in a linear shape, and the cathode region extends in a linear shape along the well region.

[A8] The semiconductor device according to any one of A1 to A7, wherein the well region is formed in an endless shape.

[A9] The semiconductor device according to any one of A1 to A8, wherein the cathode region is formed in an ended shape.

[A10] The semiconductor device according to any one of A1 to A9, wherein the well region includes a pad well region formed in an island shape and a line well region drawn out from the pad well region in a linear shape, and the cathode region is formed in a region overlapping with the line well region in a plan view.

[A11] The semiconductor device according to A10, wherein the cathode region is not formed in a region overlapping with the pad well region in a plan view.

[A12] The semiconductor device according to A10 or A11, wherein the cathode region is formed only in a region overlapping with the line well region in a plan view.

[A13] The semiconductor device according to any one of A10 to A12, further comprising: a gate pad that covers the pad well region on the first main surface.

[A14] The semiconductor device according to any one of A10 to A13, further comprising: an emitter pad that covers the active region on the first main surface.

[A15] The semiconductor device according to any one of A1 to A14, further comprising: a second-conductivity-type FL region that is formed in the surface layer portion of the first main surface at the outer region and that is at a distance from the cathode region in a direction opposite to the active region in a plan view.

[A16] The semiconductor device according to A15, wherein the FL region surrounds the well region in a plan view.

[A17] The semiconductor device according to any one of A1 to A16, further comprising: a first-conductivity-type buffer region formed in the surface layer portion of the second main surface; wherein the collector region and the cathode region are each formed in a surface layer portion closer to the second main surface in the buffer region.

This application corresponds to Japanese Patent Application No. 2019-177614 filed in the Japan Patent Office on Sep. 27, 2019, the entire disclosure of which is incorporated herein by reference. Although the embodiments of the present invention have been described in detail, these embodiments are merely concrete examples used to clarify the technical contents of the present invention, and the present invention should not be understood by being limited to these concrete examples, and the scope of the present invention is limited solely by the appended Claims.

### REFERENCE SIGNS LIST

1 Semiconductor device
2 Semiconductor substrate
4 First main surface
5 Second main surface
10 Well region
11 Pad well region
12 Line well region
13 Active region
14 Outer region
20 Collector region
21 FET structure
31 Cathode region
32 Anode region
41A FL region
41B FL region
41C FL region
41D FL region
72 Gate pad electrode
77 Emitter pad electrode
91 Semiconductor device
101 Semiconductor device
111 Semiconductor device

1. A semiconductor device comprising:
a first-conductivity-type semiconductor substrate that has a first main surface on one side and a second main surface on another side;
a second-conductivity-type well region that is formed in a surface layer portion of the first main surface and that demarcates an active region and an outer region in the semiconductor substrate;
an IGBT including a second-conductivity-type collector region formed at the active region in a surface layer portion of the second main surface and an FET structure formed at the active region in the first main surface; and
a diode that includes a first-conductivity-type cathode region formed only at the outer region in the surface layer portion of the second main surface and that has the well region serving as an anode region.

2. The semiconductor device according to claim 1, wherein the collector region is formed in a whole area of the surface layer portion of the second main surface, and
the cathode region is formed in a mode in which a second-conductivity-type impurity of the collector region is offset by a first-conductivity-type impurity.

3. The semiconductor device according to claim 1, wherein the cathode region is formed in a region overlapping with the well region.

4. The semiconductor device according to claim 1, wherein the cathode region is formed only in a region overlapping with the well region.

5. The semiconductor device according to claim 1, wherein the cathode region has a plane area that is not less than 1% and not more than 10% of a plane area of the active region.

6. The semiconductor device according to claim 1, wherein the cathode region has a plane area that is not less than 1% and not more than 5% of a plane area of the active region.

7. The semiconductor device according to claim 1, wherein the well region extends in a linear shape, and
the cathode region extends in a linear shape along the well region.

8. The semiconductor device according to claim 1, wherein the well region is formed in an endless shape.

9. The semiconductor device according to claim 1, wherein the cathode region is formed in an ended shape.

10. The semiconductor device according to claim 1, wherein the well region includes a pad well region formed in an island shape and a line well region drawn out from the pad well region in a linear shape, and
the cathode region is formed in a region overlapping with the line well region in a plan view.

11. The semiconductor device according to claim 10, wherein the cathode region is not formed in a region overlapping with the pad well region in a plan view.

12. The semiconductor device according to claim 10, wherein the cathode region is formed only in a region overlapping with the line well region in a plan view.

13. The semiconductor device according to claim 10, further comprising:
a gate pad that covers the pad well region on the first main surface.

14. The semiconductor device according to claim 10, further comprising:
an emitter pad that covers the active region on the first main surface.

15. The semiconductor device according to claim 1, further comprising:
a second-conductivity-type FL region that is formed in the surface layer portion of the first main surface at the outer region and that is at a distance from the cathode region in a direction opposite to the active region in a plan view.

16. The semiconductor device according to claim 15, wherein the FL region surrounds the well region in a plan view.

17. The semiconductor device according to claim 1, further comprising:
a first-conductivity-type buffer region formed in the surface layer portion of the second main surface;
wherein the collector region and the cathode region are each formed in a surface layer portion closer to the second main surface in the buffer region.
